(19) United States
(12) Patent Application Publication
(10) Pub. No.: US 2004/0268208 A1
(43) Pub. Date: Dec. 30, 2004

(54) Computation of branch metric values in a data detector

(75) Inventor: William M. Radich, Chaska, MN (US)

Correspondence Address: Kirk A. Cesari, Esq., Seagate Technology LLC, Intellectual Property - SHK2LG, 1280 Disc Drive, Shakopee, MN, 55379-1863, US

(73) Assignee: Seagate Technology LLC, Scotts Valley, CA

(21) Appl. No.: 10/607,967

(22) Filed: Jun. 27, 2003

(51) Int. Cl. G11C 29/00; H03M 13/03

(52) U.S. Cl. 714/770; 714/796

(57) ABSTRACT

A method of determining branch metric values in a detector is provided. The method includes receiving time variant signal samples, and computing the branch metric values as a function of transition jitter statistics corresponding to the signal samples. A detector configured to determine branch metric values as a function of transition jitter statistics corresponding to signal samples is also provided.

### FIELD OF THE INVENTION

The present invention relates to data detectors. More particularly, the present invention relates to the computation of branch metric values in a data detector, such as Viterbi-like detector employed in a read channel of a disc drive.

### BACKGROUND OF THE INVENTION

A typical disc drive includes one or more magnetic discs mounted for rotation on a hub or spindle. A typical disc drive also includes a transducer supported by a hydrodynamic air bearing which flies above each magnetic disc. The transducer and the hydrodynamic air bearing are collectively referred to as a data head. A drive controller is conventionally used for controlling the disc drive based on commands received from a host system. The drive controller controls the disc drive to retrieve information from the magnetic discs and to store information on the magnetic discs.

An electromechanical actuator operates within a negative feedback, closed-loop servo system. The actuator moves the data head radially over the disc surface for track seek operations and holds the transducer directly over a track on the disc surface for track following operations.

Information is typically stored in concentric tracks on the surface of magnetic discs by providing a write signal to the data head to encode flux reversals on the surface of the magnetic disc representing the data to be stored. In retrieving data from the disc, the drive controller controls the electromechanical actuator so that the data head flies above the magnetic disc, sensing the flux reversals on the magnetic disc, and generating a read signal based on those flux reversals. The read signal is typically conditioned and then decoded by the drive controller to recover data represented by flux reversals stored on the magnetic disc.

A typical disc drive read channel includes the data head, preconditioning logic (such as preamplification circuitry and filtering circuitry), a data detection and recovery circuit, and error detection and correction circuitry. The read channel can be implemented either as discrete circuitry, or in a drive controller associated with the disc drive.

Some conventional disc drive read channels employ data detection schemes that are designed under the assumption that additive white Gaussian noise is present in disc drives. However, it has been observed that media noise in disc drives is neither white nor stationary. The non-stationarity of the media noise results from its signal-dependent (or data-dependent) nature. Consequently, some more recently developed data detection schemes employed in read channels have utilized data-dependent noise prediction to account for the inherent data-dependence of media noise. However, these schemes suffer from the burden of requiring a large number of parameters to be estimated or tuned within the read channel.

Embodiments of the present invention provide solutions to these and other problems, and offer other advantages over the prior art.

### SUMMARY OF THE INVENTION

The present embodiments relate to a data detector in which branch metric values are computed using a transition jitter model (dependent upon positions of data transitions) of media noise, which results in a reduction in a number of parameters to be estimated in the detector, thereby addressing the above-mentioned problems.

A method of determining branch metric values in a detector is provided. The method includes receiving time variant signal samples, and computing the branch metric values as a function of transition jitter statistics corresponding to the signal samples. A detector configured to determine branch metric values as a function of transition jitter statistics corresponding to signal samples is also provided.

Other features and benefits that characterize embodiments of the present invention will be apparent upon reading the following detailed description and review of the associated drawings.

### BRIEF DESCRIPTION OF THE DRAWINGS

FIG. 1 is an isometric view of a disc drive.

FIG. 2-1 is a simplified block diagram of a read channel of the disc drive shown in FIG. 1.

FIG. 2-2 is a block diagram of a data detection and recovery circuit according to the present invention.

FIG. 3 is a simplified block diagram illustrating a generic branch metric calculation unit in accordance with an embodiment of the present invention.

FIG. 4 is a conceptual flowchart showing branch metric computation for a general state transition in accordance with an embodiment of the present invention.

FIG. 5 is an exemplary trellis diagram for illustrating an embodiment of the present invention.

FIG. 6 is a table including decimal state representation information for illustrating an embodiment of the present invention.

FIGS. 7 and 8 are plots illustrating a comparison of results obtained using prior art branch metric computation techniques and branch metric computation techniques of the present invention.

### DETAILED DESCRIPTION OF ILLUSTRATIVE EMBODIMENTS

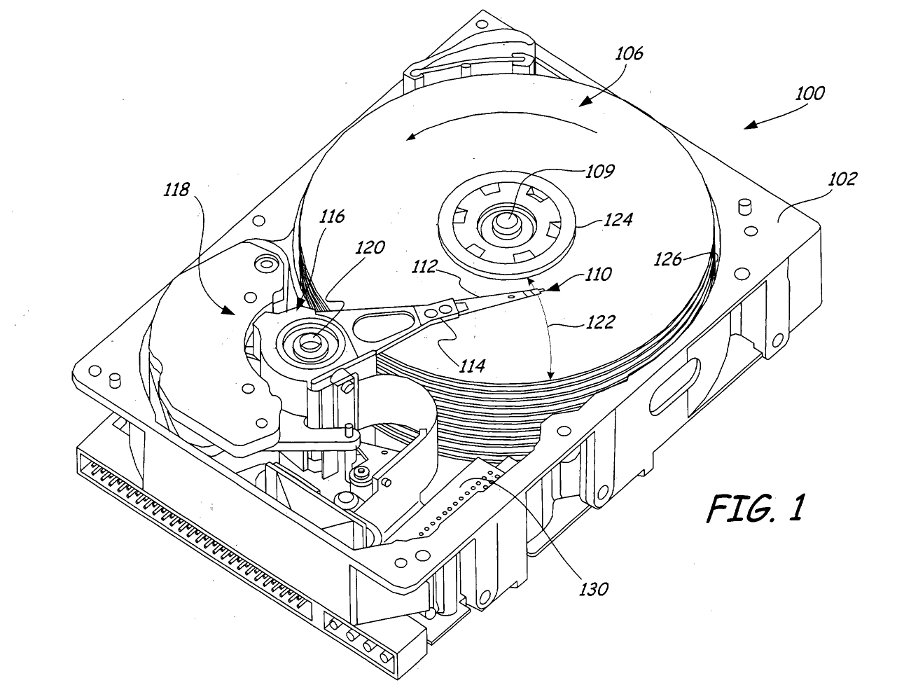

FIG. 1 is an isometric view of a disc drive 100 in which embodiments of the present invention are useful. The same reference numerals are used in the various figures to represent the same or similar elements. Disc drive 100 includes a housing with a base 102 and a top cover (not shown). Disc drive 100 further includes a disc pack 106, which is mounted on a spindle motor (not shown) by a disc clamp 108. Disc pack 106 includes a plurality of individual discs, which are mounted for co-rotation about central axis 109. Each disc surface has an associated disc head slider 110 which is mounted to disc drive 100 for communication with the disc surface. Surfaces of disc 106 are usually divided into zones, with each zone including multiple adjacent tracks. In the example shown in FIG. 1, sliders 110 are supported by suspensions 112 which are in turn attached to track accessing arms 114 of an actuator 116. The actuator shown in FIG. 1 is of the type known as a rotary moving coil actuator and includes a voice coil motor (VCM), shown generally at 118. Voice coil motor 118 rotates actuator 116 with its attached heads 110 about a pivot shaft 120 to position heads 110 over a desired data track along an arcuate path 122 between a disc inner diameter 124 and a disc outer diameter 126. Voice coil motor 118 is driven by servo electronics, which is included in control circuitry (or controller) 130, based on signals generated by heads 110 and a host computer (not shown).

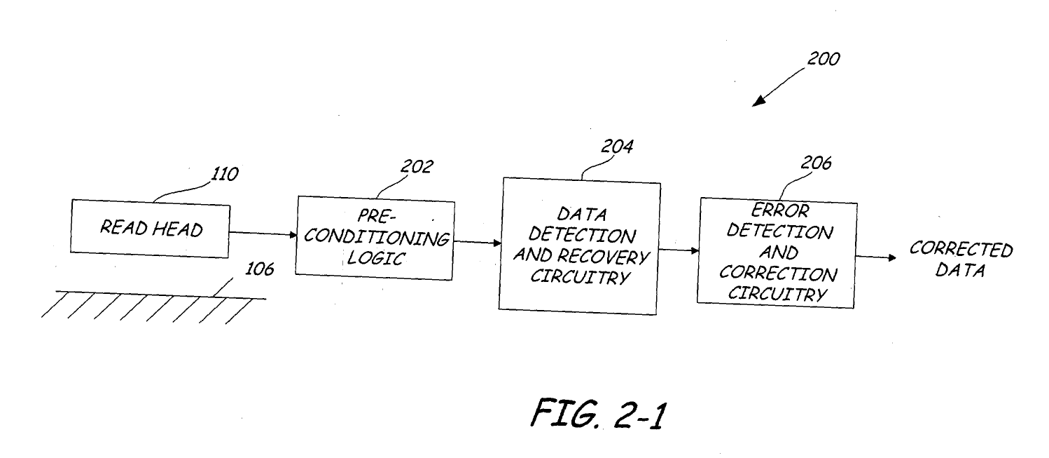

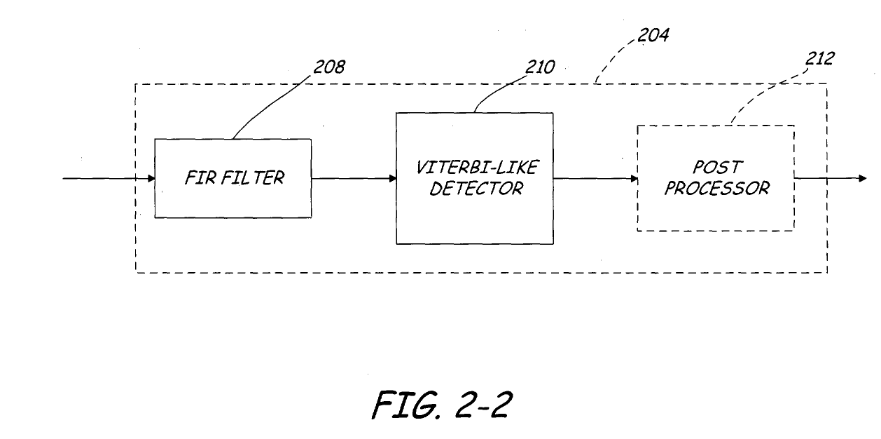

FIG. 2-1 is a simplified block diagram of a read channel 200 of disc drive 100. For simplification, only one disc and one head are shown in FIG. 2. Read channel 200 includes magnetic disc 106, data head 110, preconditioning logic 202, data detection and recovery circuit 204 and error detection and correction circuit 206. Preconditioning logic 202, data detection and recovery circuit 204 and error detector and correction circuit 206 are, in some embodiments, a part of control circuitry 130 (FIG.1).

As mentioned above, in operation, controller 130 receives a command signal from the host system which indicates that a certain portion of disc 106 is to be accessed. In response to the command signal, servo electronics within controller 130 produces control signals that direct voice coil motor 118 to rotate actuator 116 and thereby position head 110 over a desired track.

Head 110 develops a read signal indicative of flux reversals in the track over which head 110 is positioned. The read signal is provided to preconditioning logic 202 which typically includes a preamplifier, an analog to digital converter and filtering circuitry. The amplified and filtered signal is provided to data detection and recovery circuitry 204 which recovers data encoded on the surface of disc 106. Once the data is detected and recovered, it is provided to error detection and correction circuitry 206 which may be based on an error correction code (ECC), such as a Reed-Solomon code. Error detection and correction circuit 206 detects whether any errors have occurred in the data read back from the disc. Further, in some embodiments, error detection and correction circuit 206 is provided with error correction logic which is used to correct errors discovered in the data read back from disc 106. The corrected data is provided to the host system.

Data detection and recovery circuitry 204 typically includes a data detector (such as a Viterbi-like detector) that helps recover data from the readback signal.

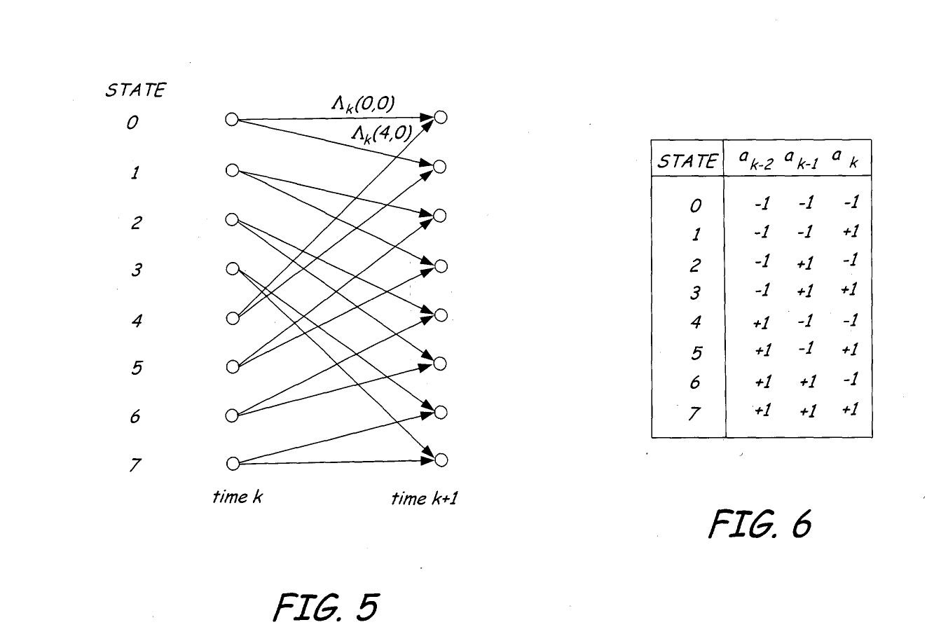

Operation of a Viterbi-like detector is more easily understood using a trellis diagram (such as the trellis diagram shown in FIG. 5), which is a typical state machine diagram with an additional parameter, discrete time. The Viterbi-like detector operates by selecting a most likely path through the trellis diagram given some received sequence. A “metric” is kept for each state at each time, and a “previous state” is also kept for each state at each time. As new samples are received, new metrics are computed.

As mentioned above, some conventional disc drive read channels employ data detection schemes that are designed under the assumption that additive white Gaussian noise is present in disc drives. In such schemes, trellis/tree branches are usually computed as Euclidian metrics. In general, the bit error rate (BER) performance of a detector employing a Euclidian metric computation method is relatively low. As noted above, certain other prior art data detection schemes utilize data-dependent noise prediction to account for the inherent data-dependence of media noise. However, these data detection schemes suffer from the burden of requiring a large number of parameters to be estimated or tuned within the read channel.

Under the present invention, a scheme for determining branch metric values in a detector is provided in which branch metric values are computed using a transition jitter model of media noise. This results in a reduction in a number of parameters to be estimated in the detector. The present invention differs from previous solutions in that noise statistics (related to amplitude-distortion of signals received by the detector) are not explicitly estimated for each hypothesized data sequence corresponding to a particular trellis branch. Instead, a maximum of only two parameters need be estimated for a particular head and zone combination. These two parameters, along with a hypothesized data sequence, and an equalized transition response uniquely determine all required branch metrics, and implicitly determine the overall noise statistics (transition jitter noise and amplitude-related noise) corresponding to each branch. In addition, the metric naturally exploits the non-causal characteristics of transition jitter. The calculation of parameters and the determination of branch metric values in accordance with the present invention are described further below. The method of determining branch metric values in accordance with the present invention can be used to provide soft or hard decisions, in both trellis and post-processor architectures. A data detector, which implements the branch metric computation scheme of the present invention, is described below in connection with FIG. 2-2.

FIG. 2-2 shows a block diagram of data detection and recovery circuit 204 in accordance with an embodiment of the present invention. While data detection and recovery circuit 204 will typically include conventional pulse detection and qualification circuitry, it also includes finite impulse response (FIR) filter 208 and Viterbi-like detector 210. In some embodiments, in addition to a primary detector (such as Viterbi-like 210), a post processor 212 is included to refine the output of the primary detector. In designing Viterbi-like detector 210 of the present invention, effects of wide-band additive noise and media jitter in samples input into detector 210 are taken into consideration. An example algorithm suitable for implementation in Viterbi-like detector 210 and/or post processor 212 is described below in connection with Equations 1-38.

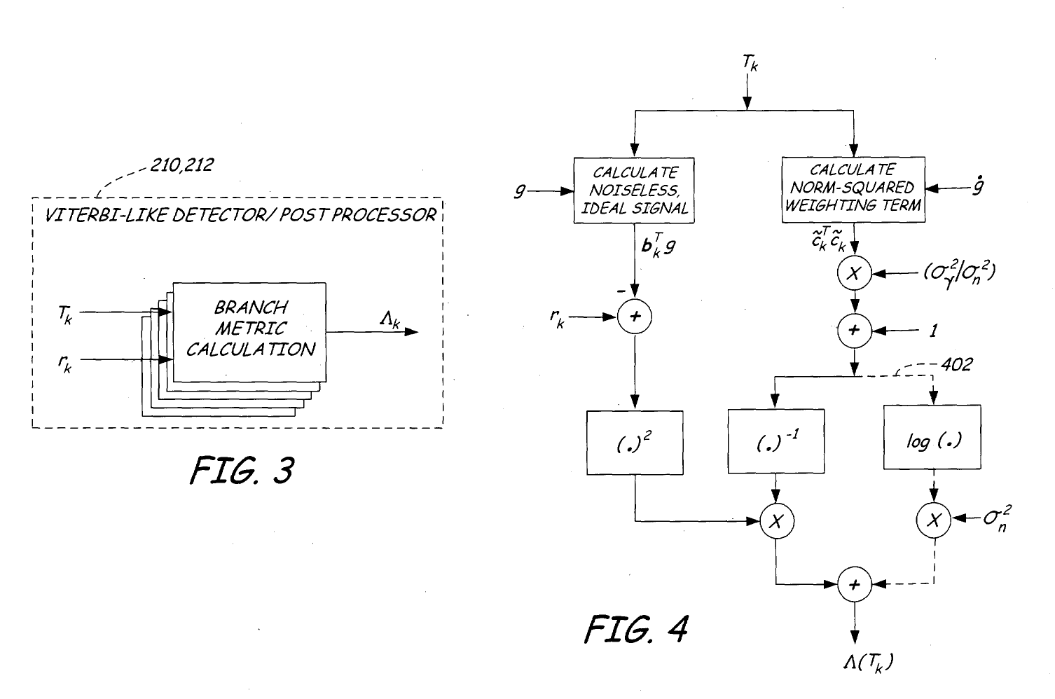

In the example algorithm, the derivation of jitter-noise metrics is carried out from a Bayesian viewpoint, where transition jitter is treated as a random, nonlinear, nuisance parameter. The example algorithm is described below by first developing an appropriate background and model notation. This is followed by a general discussion of the proposed Bayesian approach and the simplified first-order Taylor series model for jitter. An optimal Bayes cost function for first-order jitter, which is inherently non-recursive (not implementable in a trellis search structure), is then derived. This is followed by the derivation of a recursive branch metric that can be modified, as discussed in connection with FIGS. 3-6, for practical implementation in a Viterbi-like detector.

1) Discrete Time Media Jitter Model

Let aₖ ∈[+/−1] represent a non-return to zero (NRZ), bipolar sequence of encoded, precoded data to be written to the disk, with the transition sequence bk defined by

$${b}_{k} = \frac{1}{2} ( {a}_{k} - {a}_{k - 1} ) \qquad Equation 1$$

Assume a symbol-rate sampled, discrete-time equivalent, equalized, transition response is given by the sequence gₖ, so that the combined effects of wide-band additive noise and media jitter can be modeled at the input to a detector as the received sample

$${r}_{k} = {\sum }_{l} {b}_{l} g ( k - l - {γ}_{l} ) + {n}_{k} \qquad Equation 2$$

where n is the normalized, random jitter parameter associated with the l^{th} transition symbol bₗ, and nₖ represents the contribution of wide-band, additive, Gaussian noise with variance σₙ². Without loss of generality it can be assumed that nₖ is white, by simply assuming that rₖ has been effectively filtered so as to remove any correlation in nₖ, and thus all equalization is assumed to be absorbed in gₖ. Note that for practical direct current (DC)-free inter-symbol interference (ISI) channels (e.g. longitudinal recording) gₖ will have a finite support. However, it is shown later in the application how the proposed Bayesian cost function is easily modified for the case of an arbitrary ISI channel that does not have a DC null.

2) Bayesian Marginal Approach for First Order Jitter

Let the column vector r=[r₀, r₁, . . . , r_{M-1}]_{T} represent M received samples of rₖ, due to the transmission of the N<M transition symbols b=[b₀, b₁, . . . , b_{N-1}]^{T}. Corresponding to the transition symbol vector, is the (considered random) vector of jitter parameters γ=[γ₀, γ₁, . . . , γ_{N-1}]^{T}. The likelihood function, conditioned also on γ, is thus

$$p ( r \vert b , γ , {σ}_{n}^{2} ) = {Π}_{k} p ( {r}_{k} \vert b , γ , {σ}_{n}^{2} ) . \qquad Equation 3$$

If the Bayesian viewpoint of treating γ as a random nuisance parameter with the assumed prior density function p(γ/b) is adopted, the choice is either to consider the joint maximum a-posterori (MAP) estimates of b and γ, or to integrate out the nuisance parameter from Equation 3, resulting in the marginal:

p(r|b, σₙ²)=∫_{γ}p(r|b, γ, σₙ²)p(γ|b)dγ Equation 4

Here, the marginal approach is chosen because it requires estimation of the transition symbol sequence only, whereas the joint MAP estimation of b and γessentially requires the estimation of two parameters, one of which is non-linear, for each observed sample.

Given the preference for a marginal approach, however, leads to the need for dealing with a major obstacle. Note that g is a non-linear function of γ, and therefore a closed form expression for Equation 4 does not exist in general. This situation is remedied by utilizing a first-order Taylor series jitter model to replace Equation 2:

$$\begin{matrix}{r}_{k} = {\sum }_{l = 0}^{N - 1} b [ {g}_{k - l} - {γ}_{l} {\dot{g}}_{k - l} ] + {n}_{k} \\ where & Equation 5 \\ {\dot{g}}_{k} \underline{\underline{def}} T \frac{ⅆ}{ⅆ t} g ( t ) {\vert}_{t = kT} & Equation 6\end{matrix}$$

where

$$\underline{\underline{def}}$$

represents defines.' For notational convenience, the linear part of Equation 5 can be written as

$${\sum }_{l} {b}_{l} {g}_{k - l} = {g}_{k}^{T} b \qquad Equation 7$$

and the jitter contribution is expressed as

$$\begin{matrix}{\sum }_{l} {b}_{l} {γ}_{l} {\dot{g}}_{k - 1} = {γ}^{T} {c}_{k} ( b ) \\ where & Equation 8 \\ {g}_{k} {\underline{\underline{def}} [ {g}_{k} , {g}_{k - 1} , … , {g}_{k - N + 1} ]}^{T} & Equation 9 A \\ {\dot{g}}_{k} {\underline{\underline{def}} [ {\dot{g}}_{k} , {\dot{g}}_{k - 1} , … , {\dot{g}}_{k - N + 1} ]}^{T} \\ and & Equation 9 B \\ {c}_{k} ( b ) \underline{\underline{def }} b Θ {\dot{g}}_{k} & Equation 10\end{matrix}$$

where ‘Θ’ represents vector element-by-element multiplication.

3) Non-Recursive Solution

Assuming that each transition is associated with an independent, and identically Gaussian-distributed, γyields

$$\begin{matrix}p ( γ \vert b ) = p ( γ ) \\ = {( 2 π )}^{- \frac{N}{2}} {σ}_{γ}^{- N} exp ( - \frac{1}{2 {σ}_{γ}^{2}} {\vert γ \vert}^{2} )\end{matrix} \qquad Equation 11$$

With Equation 11 and the uncorrelated, Gaussian-distributed, assumption for nₖ, Equation 4 can be solved and the following cost function can be derived

$$\begin{matrix}{v}_{Bayes} ( b ) \underline{\underline{def}} - log ( p ( r \vert b , {σ}_{n}^{2} ) ) = {σ}_{n}^{2} log \vert R ( b ) \vert + {( r - Gb )}^{T} {\vert R ( b ) \vert}^{- 1} ( r - Gb ) \\ where & Equation 12 \\ R ( b ) \underline{\underline{def}} {I}_{M} + ( \frac{{σ}_{γ}^{2}}{{σ}_{n}^{2}} ) {C ( b )}^{T} C ( b ) & Equation 13\end{matrix}$$

$$G \underline{\underline{def}} [ \begin{matrix}⋯ & {g}_{0}^{T} & ⋯ \\ ⋯ & {g}_{1}^{T} & ⋯ \\ & ⋮ & \\ ⋯ & {g}_{M - 1}^{T} & ⋯\end{matrix} ] \qquad Equation 15$$

Note that the cost function given by Equation 12 is not recursive because the inverse of the data-dependent correlation matrix R(b) is in general not diagonal, except for the trivial cases of b=0 or σₙ²=0. Also, for σₙ²=0, Equation 12 reduces to a conventional or standard Euclidean metric

V(b)=|r−Gb|² Equation 16

One method for converting Equation 12 into a recursive form is to approximate R(b)⁻¹ with an L-banded matrix, meaning that it has 2L+1 non-zero diagonals. This is equivalent to assuming that media and electronic noise contributions are lumped together as a data-dependent, L^{th}-order autoregressive (AR) process, and results in corresponding data-dependent noise prediction architecture with L noise-predictive taps. The downside to this approach is that there is no straightforward method for connecting the large number of data-dependent parameters required for detection to known quantities a-priori, and thus requires the estimation of these parameters for every head and zone combination.

However, it is noted that R(b) is determined completely by the data transition sequence b (the multi-dimensional vector with which the cost function is searched over), the a-priori known transition response derivative gₖ (via Equations 14 and 10), σ_{γ}² and σₙ². The jitter variance parameter σ_{γ}² can be determined relatively accurately a-priori for a given magnetic media formulation and zone BPI (bits per inch), and thus a Bayesian detector may require only the tuning/estimation of σₙ².

This observation serves as motivation to modify the Bayesian approach to derive a recursive media-noise cost function that requires only the knowledge of σ_{γ}² and σₙ².

4) Recursive Solution

One approach to deriving a recursive cost-function is to neglect all off-diagonal terms in Equation 13. This is equivalent to using the following as approximations for Equations 3 and 4

$$\begin{matrix}p ( {r}_{k} \vert b , {σ}_{n}^{2} ) = {\int }_{γ}^{} p ( {r}_{k} \vert b , γ , {σ}_{n}^{2} ) p ( γ \vert b ) ⅆ γ & Equation 17 \\ p ( r \vert b , {σ}_{n}^{2} ) \approx {\prod }_{k} p ( {r}_{k} \vert b , {σ}_{n}^{2} ) & Equation 18\end{matrix}$$

Solving Equation 17 results directly in the branch metric (to be minimized)

$$\begin{matrix}Λ ( {r}_{k} , b ) {=}^{def} - log p ( {r}_{k} \vert b , {σ}_{n}^{2} ) \\ = {σ}_{n}^{2} log ( 1 + ( \frac{{σ}_{γ}^{2}}{{σ}_{n}^{2}} ) {c}_{k}^{T} {c}_{k} ) + \frac{{( {r}_{k} - {b}^{T} {g}_{k} )}^{2}}{( 1 + ( \frac{{σ}_{γ}^{2}}{{σ}_{n}^{2}} ) {c}_{k}^{T} {c}_{k} )}\end{matrix} \qquad Equation 19$$

Equation 19 is further simplified by ignoring the leading bias term, thus resulting in

$$\tilde{Λ} ( {r}_{k} , b ) {=}^{def} \frac{{( {r}_{k} - {b}^{T} {g}_{k} )}^{2}}{( 1 + ( \frac{{σ}_{γ}^{2}}{{σ}_{n}^{2}} ) {c}_{k}^{T} {c}_{k} )} \qquad Equation 20$$

An attractive feature of Equation 20 is that it requires knowledge only of the ratio of jitter to additive noise variances, and therefore this cost function may be interpreted as a branch metric that can be made increasingly robust to transition jitter by simply increasing this single parameter.

5) Implementation as a Modified Viterbi Detector Equation 19 is examined in more detail for practical implementation in a Viterbi detector. In particular, by accounting for the finite support of gₖ and gₖ, the dependence of Λ(.) on the entire block of N symbols b can be dropped. It is first assumed that the equalized transition response g is causal, with I nonzero terms (later, this assumption is relaxed and the unit pulse response for DC-content channels is used). The derivative of the transition response will, in general, contain both causal and non-causal terms. A new, length (I₁+I₂+1) transition derivative response vector is defined:

$$\dot{g} {=}^{def} {[ {\dot{g}}_{- {I}_{1}} , … , {\dot{g}}_{- I} , {\dot{g}}_{0} , {\dot{g}}_{I} , … , {\dot{g}}_{{I}_{2}} ]}^{T} \qquad Equation 21$$

and assuming that I₂>I−1 new length vectors (I₁+I₂+1) for the transition sequence and transition response are defined as

$$\begin{matrix}{b}_{k} {=}^{def} {[ {b}_{k + {I}_{1}} , … , {b}_{k + 1} , {b}_{k - 1} , … , {b}_{k - {I}_{2}} ]}^{T} & Equation 22 \\ and & \\ g {=}^{def} {[ 0 , … , 0 , {g}_{0} , {g}_{1} , … , {g}_{I - 1} , 0 , …0 ]}^{T} & Equation 23\end{matrix}$$

where the transition response vector has I₁ leading zeros before the g₀ term, and I₂−I+1 zeros following the g_{I-1} term.

With the vectors defined above, the branch metrics given by Equations 19 and 20 are re-written in the, more appropriate, recursive forms as

$$\begin{matrix}Λ ( {r}_{k} , {b}_{k} ) = {σ}_{n}^{2} log ( 1 + ( \frac{{σ}_{γ}^{2}}{{σ}_{n}^{2}} ) {\tilde{c}}_{k}^{T} {\tilde{c}}_{k} ) + \frac{{( {r}_{k} - {b}_{k}^{T} g )}^{2}}{( 1 + ( \frac{{σ}_{γ}^{2}}{{σ}_{n}^{2}} ) {\tilde{c}}_{k}^{T} {\tilde{c}}_{k} )} & Equation 24 \\ and & \\ \tilde{Λ} ( {r}_{k} , {b}_{k} ) = \frac{{( {r}_{k} - {b}_{k}^{T} g )}^{2}}{( 1 + ( \frac{{σ}_{γ}^{2}}{{σ}_{n}^{2}} ) {\tilde{c}}_{k}^{T} {\tilde{c}}_{k} )} & Equation 25 \\ where & \\ {\tilde{c}}_{k} {=}^{def} {b}_{k} {Θ}_{g}^{•} & Equation 26\end{matrix}$$

As mentioned above, the equalized transition response vector g may not actually have finite support, in which case, with the (assumed finite support) pulse response pₗ and the NRZ data sequence aₖ, the noiseless the ideal channel output term in Equation 24 is computed as

$$\begin{matrix}{b}_{k}^{T} g = {\sum }_{l - 0}^{I - 1} {g}_{l} {b}_{k - l} \\ = \frac{1}{2} {\sum }_{l = 0}^{I - 1} {g}_{l} ( {a}_{k - l} - {a}_{k - l - 1} ) \\ = {\sum }_{l = 0}^{I} {p}_{l} {a}_{k - l}\end{matrix} \qquad Equation 27$$

Likewise, the remaining terms of Equation 24 are converted to the NRZ domain by writing

$${\tilde{c}}_{k}^{T} {\tilde{c}}_{k} = \frac{1}{4} {\sum }_{l = - {I}_{1}}^{{I}_{2}} {{\dot{g}}_{l}^{2} ( {a}_{k - l} - {a}_{k - l - 1} )}^{2} \qquad Equation 28$$

Note that the inner product in Equation 28 represents the norm-square of \tilde{c}ₖ, and thus satisfies

\tilde{c}ₖ^{T\tilde{c}}ₖ≧0 Equation 29

Also, note that this term is exactly zero only for the case of no transitions:

bₖ=0, and thus the overall inverse weighting term

$$( 1 + ( \frac{{σ}_{γ}^{2}}{{σ}_{n}^{2}} ) {\tilde{c}}_{k}^{T} {\tilde{c}}_{k} )$$

imposes a

higher penalty in Equations 24 and 25 for the case of either an increasing σ_{γ}², and/or for more transitions in bₖ. Conversely, this weighting term goes to unity if either σ_{γ}²=0, or bₖ=0, in which case, both Equation 24, and Equation 25 become the standard Euclidean metric for an ISI channel with no transition jitter:

Λ(rₖ,bₖ)Euc=(rₖ−bₖ^{T}g)² Equation 30

An examination of Equation 28 suggests the following definition of a trellis detector state at time k:

Xₖ=(a_{k-I}_{₂}₋₁,a_{k-I}_{₂}, . . . ,aₖ,a_{K+I},a_{k+I}_{₁}₋₁,a_{k+I}_{₁}) Equation 31

and shows that Equations 24 and 25 require a trellis with 2^{(I}^{₁}^{+I}^{₂}⁺¹⁾ states, an expansion over the 2^{I} states required if σ_{γ}²=0. Note also that the non-causal effects of transition jitter are reflected in Equation 31. Corresponding to the above state 20 definition, there are 2^{(I}^{₁}^{+I}^{₂}⁺²⁾ possible transitions between states at time k:

$$\begin{matrix}{T}_{k} = ( {x}_{k} , {x}_{k + 1} ) \\ = ( {a}_{k - {I}_{2} - 1} , {a}_{k - {I}_{2} , … ,} {a}_{k} , {a}_{k + 1} , {a}_{k + {I}_{1} - 1} , {a}_{k + {I}_{1}} )\end{matrix} \qquad Equation 32$$

and thus the branch metrics in Equations 24 and 25 can be explicitly denoted as functions of the current equalized sample rₖ, and the state transition Tₖ as, respectively, Λ(rₖ,Tₖ) and \tilde{Λ}(rₖ,Tₖ). FIG. 3 illustrates the generic branch metric calculation unit, and FIG. 4 shows a conceptual flowchart that further describes the branch metric computation for a general state transition. Inclusion of dashed path 402 in FIG. 4 results in the branch metric given in Equation 24. If dashed path 402 is ignored, the result is Equation 25.

6) 8-State Modified Viterbi Example

As in a conventional binary-symbol Viterbi trellis search algorithm, there are two branch metrics going into each trellis state, reflecting the local likelihood of one unique state transition over another, and these branch metrics are summed over the length of the trellis to represent an overall path metric. For this example, an 8-state trellis (shown in FIG. 5), with I=2, I₁=1, and I₂=1. The decimal number associated with each state in FIG. 5 is related to the state definition in Equation 31 by the table shown in FIG. 6.

From Equation 27 the ideal, linear, equalized channel output can be 15 represented as a function of state transition Tₖ=(aₖ₋₂, aₖ₋₁, aₖ₊₁) as

$${b}_{k}^{T} g = \frac{1}{2} [ {g}_{0} ( {a}_{k} - {a}_{k - 1} ) + {g}_{1} ( {a}_{k - 1} - {a}_{k - 2} ) ] \qquad Equation 33$$

and from Equation 28, the norm-squared term \tilde{c}ₖ^{T}\tilde{c}ₖ as

$${\tilde{c}}_{k}^{T} {\tilde{c}}_{k} = \frac{1}{4} [ {{g}_{- 1}^{{•}^{2}} ( {a}_{k + 1} - {a}_{k} )}^{2} + {{g}_{0}^{{•}^{2}} ( {a}_{k} - {a}_{k - 1} )}^{2} + {{g}_{1}^{{•}^{2}} ( {a}_{k - 1} - {a}_{k - 2} )}^{2} ] \qquad Equation 34$$

At the top of FIG. 5 the two possible transitions from time k that can lead to state 0 at time k+l, denoted here for simplicity as Λₖ(0, 0), and Λₖ(4, 0), are shown.

Note that in this setting, Λₖ(i, j) signifies the branch metric resulting from a transition at time k from state i, to state j at time k+1. From the table in FIG. 6, Λₖ(0, 0) can be identified with the transition in NRZ Tₖ=(−1, −1, −1, −1), and Λₖ(4, 4) with can be identified with the transition Tₖ=(+1, −1, −1, −1). Thus Equations 33 or 34 can be used in Equations 24 or 25 to obtain

Λₖ(0,0)=rₖ² Equation 35

$${Λ}_{k} ( 4 , 0 ) = {σ}_{n}^{2} log ( 1 + ( \frac{{σ}_{γ}^{2}}{{σ}_{n}^{2}} ) {g}_{1}^{{•}^{2}} ) + \frac{{( {r}_{k} + {g}_{1} )}^{2}}{( 1 + ( \frac{{σ}_{γ}^{2}}{{σ}_{n}^{2}} ) {g}_{1}^{{•}^{2}} )} \qquad Equation 36$$

or

\tilde{Λ}ₖ(0,0)=rₖ² Equation 37

$${\tilde{Λ}}_{k} ( 4 , 0 ) = \frac{{( {r}_{k} + {g}_{1} )}^{2}}{( 1 + ( \frac{{σ}_{γ}^{2}}{{σ}_{n}^{2}} ) {g}_{1}^{{•}^{2}}} \qquad Equation 38$$

7) Performance Comparison

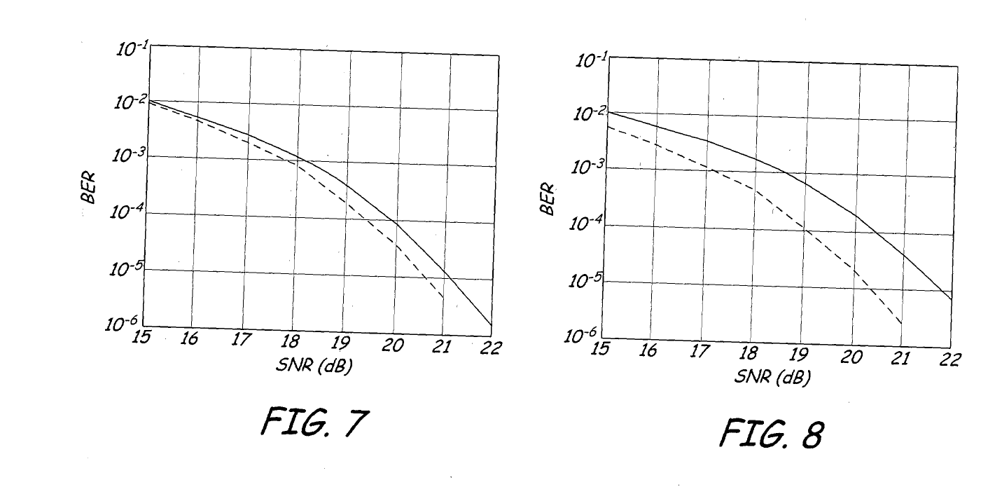

FIGS. 7 and 8 are plots of results obtained from longitudinal recording simulations with a Lorentzian transition response model. Gaussian-distributed jitter parameters are generated for each transition to represent media noise. In obtaining the overall channel signal-to-noise ratio (SNR), the total received noise power used is the sum of discrete-time signal variances due to additive white Gaussian noise, and Gaussian transition jitter, as observed through an ideal low-pass filter (transition width variation is ignored here). In FIGS. 6 and 7, the vertical axis represents BER and the horizontal axis represents SNR in decibels (dB). Plots of FIGS. 6 and 7 represented by solid lines correspond to the conventional Euclidian metric and plots represented by dashed lines correspond to the recursive Bayes technique of the present invention. Specifically, FIG. 7 compares the BER performance of the Euclidean metric (Equation 30) versus the recursive Bayesian metric (Equation 25) for a symbol density of 2.25 and a jitter/electronic noise mix of 50/50. A gain of about 0.5 dB is demonstrated for the recursive Bayesian metric over the Euclidean metric at about 1E-5 error rates. FIG. 8 shows BER results where the mix of jitter/electronic noise is increased to 80/20. Here the recursive Bayesian metric demonstrates a gain of about 1.25 dB at 1e-5. The results obtained from the longitudinal recording simulations show that the BER performance of a detector employing the recursive Bayesian metric computation technique of the present invention is substantially better than the BER performance of a detector employing the prior art Euclidian metric computation method.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application for the data detector while maintaining substantially the same functionality without departing from the scope and spirit of the present invention. In addition, although the preferred embodiment described herein is directed to a data detector for a read channel of a disc drive data storage system, it will be appreciated by those skilled in the art that the teachings of the present invention can be applied to data detectors employed in other systems, without departing from the scope and spirit of the present invention. Further, the data detector may be implemented in hardware or software. The disc drive can be based upon magnetic, optical, or other storage technologies and may or may not employ a flying slider. As mentioned above, transition jitter is a relatively dominant component of media noise and is dependent upon positions of data transitions. Transition jitter statistics include statistical data corresponding to transition jitter, such as transition jitter variance, used in the above equations.

What is claimed is:

1. A method of determining branch metric values in a detector, the method comprising:
(a) receiving time variant signal samples; and
(b) computing the branch metric values as a function of transition jitter statistics corresponding to the signal samples.

2. The method of claim 1 wherein the transition jitter statistics comprise transition jitter variance.

3. The method of claim 1 wherein the computing step (b) further comprises computing the branch metric values as a function of wide-band additive noise corresponding to the signal samples.

4. The method of claim 1 wherein the computing step (b) further comprises computing the branch metric values as a function of hypothesized data sequences corresponding to trellis branches of the detector.

5. The method of claim 1 wherein the computing step (b) further comprises computing the branch metric values as a function of an equalized transition response derivative of the signal samples.

6. The method of claim 1 wherein a derivation of transition jitter statistics is carried out from a Bayesian viewpoint, wherein transition jitter is treated as a random, nonlinear, nuisance parameter.

7. The method of claim 1 wherein the detector is a hard decision detector.

8. The method of claim 1 wherein the detector is a soft decision detector.

9. The method of claim 1 wherein the detector is a part of a read channel of a disc drive data storage system.

10. The method of claim 1 wherein the detector is a post processor, which refines signals output by a primary detector.

11. A detector comprising:
branch metric calculation modules configured to determine branch metric values by:
(a) receiving time variant signal samples; and
(b) computing the branch metric values as a function of transition jitter statistics corresponding to the signal samples.

12. The apparatus of claim 11 wherein the transition jitter statistics comprise transition jitter variance.

13. The apparatus of claim 11 wherein the branch metric calculation modules are further configured to carry out the computing step (b) by computing the branch metric values as a function of wide-band additive noise corresponding to the signal samples.

14. The apparatus of claim 11 wherein the branch metric calculation modules are further configured to carry out the computing step (b) by computing the branch metric values as a function of hypothesized data sequences corresponding to trellis branches of the detector.

15. The apparatus of claim 11 wherein the branch metric calculation modules are further configured to carry out the computing step (b) by computing the branch metric values as a function of an equalized transition response derivative of the signal samples.

16. The apparatus of claim 11 wherein a derivation of transition jitter statistics is carried out from a Bayesian viewpoint, wherein transition jitter is treated as a random, nonlinear, nuisance parameter.

17. The apparatus of claim 11 wherein the detector is a hard decision detector.

18. The apparatus of claim 11 wherein the detector is a soft decision detector.

19. The apparatus of claim 11 wherein the detector is a part of a read channel of a disc drive data storage system.

20. A detector comprising:
means for computing branch metric values as a function of transition jitter statistics corresponding to signal samples received by the detector.
